(19) United States
(12) Patent Application Publication
(10) Pub. No.: US 2026/0247641 A1
(43) Pub. Date: Aug. 20, 2026

(54) METHOD OF MANUFACTURING A POWER DIODE

(71) Applicant: STMICROELECTRONICS INTERNATIONAL N.V., Geneva (CH)

(72) Inventor: Fabien ALLANIC, Tours (FR)

(21) Appl. No.: 19/529,851

(22) Filed: Feb. 4, 2026

(30) Foreign Application Priority Data
Feb. 18, 2025 (FR) 2501660

(51) Int. Cl. H10D 8/01

(52) U.S. Cl. CPC H10D 8/041; H10D 8/045

(57) ABSTRACT

The present disclosure relates to a power diode. A method of manufacturing a power diode comprises: forming a first structure comprising a first semiconductor substrate doped with a first conductivity type, and, in the first semiconductor substrate, on the side of a first surface, a first doped region of second conductivity type, opposite to the first conductivity type; forming a second structure comprising a second semiconductor substrate, and, on the second semiconductor substrate, on the side of a first surface, a first layer, the second semiconductor substrate and first layer being doped with the first conductivity type, the first layer doped more heavily; diffusing platinum atoms in the first semiconductor substrate; and assembling the first structure and the second structure by placing into contact a second surface of the first semiconductor substrate of the first structure and a second surface of the second semiconductor substrate of the second structure.

### CROSS REFERENCE TO RELATED APPLICATIONS

This application claims the priority benefit of French Patent Application Number 2501660, filed on February 18, 2025, entitled “PROCÉDÉ DE FABRICATION D’UNE DIODE DE PUISSANCE” which is hereby incorporated by reference to the maximum extent allowable by law.

### TECHNICAL FIELD

The present disclosure generally concerns the field of semiconductor electronic components and more particularly the field of vertical power diodes.

### BACKGROUND

A vertical power diode comprising a stack of a P-type doped layer, of a lightly-doped semiconductor layer, and of an N-type doped layer has already been provided. In such a structure, in the absence of a voltage, few charge carriers are present in the lightly-doped layer, which results in a low conductivity of the diode. During the application of a voltage, the charge carriers are injected into the lightly-doped layer, which allows the flowing of current.

Such a power diode is adapted to efficiently operating at relatively high frequencies due to the fact that the lightly-doped layer decreases the capacitance of the PN junction. Further, the lightly-doped layer enables the diode to withstand a relatively high reverse voltage and allows a faster switching between a conductive state and a non-conductive state.

It would be desirable to overcome at least partly certain disadvantages of known embodiments of power diodes.

### BRIEF SUMMARY

For this purpose, an embodiment provides a method of manufacturing a power diode comprising the following steps: forming a first structure comprising a first semiconductor substrate doped with a first conductivity type, and, in the first semiconductor substrate, on the side of a first surface of the first semiconductor substrate, a first doped region of a second conductivity type, opposite to the first conductivity type; forming a second structure comprising a second semiconductor substrate, and, on the second semiconductor substrate, on the side of a first surface of the second semiconductor substrate, a first layer, the second semiconductor substrate and the first layer being doped with the first conductivity type, the first layer being more heavily doped than the second semiconductor substrate; diffusing platinum atoms in the first semiconductor substrate; and assembling the first structure and the second structure by placing into contact a second surface of the first semiconductor substrate of the first structure, opposite to the first surface, and a second surface of the second semiconductor substrate of the second structure, opposite to the first surface.

According to an embodiment, during step b), the first layer is formed by epitaxy on the first surface of the second substrate.

According to an embodiment, the second structure formed during step b) further comprises a field stop layer between the second substrate and the first layer, the field stop layer being doped with the first conductivity type.

According to an embodiment, the field stop layer is formed by epitaxy on the first surface of the second substrate.

According to an embodiment, during step a), the first region is formed by implantation of dopants from the first surface of the first substrate.

According to an embodiment, step c) comprises the forming of a platinum metal layer on the first surface of the first substrate of the first structure and an anneal of the structure thus obtained so as to obtain a platinum diffusion in the first substrate.

According to an embodiment, step d) is carried out by an atomic diffusion bonding method.

According to an embodiment, step d) is carried out by a surface activation bonding method.

According to an embodiment, step d) is carried out by a dilute hydrofluoric acid bonding method.

According to an embodiment, step d) is carried out by a reconstructed surface bonding method.

Another embodiment provides a power diode comprising:

a first doped substrate of a first conductivity type;

a first region, in the first semiconductor substrate, on the side of a first surface of the first semiconductor substrate, the first region being doped with a second conductivity type, opposite to the first conductivity type;

a second doped substrate of the first conductivity type;

a first layer, on the second semiconductor substrate, on the side of a first surface of the second semiconductor substrate, the first layer being doped with the first conductivity type, the first layer being more heavily doped than the second semiconductor substrate;

the first substrate being in contact, by a second surface, opposite to the first surface, with a second surface of the second substrate, opposite to the first surface, and wherein the first semiconductor substrate comprises a platinum concentration higher than a platinum concentration in the second semiconductor substrate.

According to an embodiment, the diode further comprises a field stop layer between the second substrate and the first layer, the field stop layer being doped with the first conductivity type.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an example of a power diode; and

FIG. 2A, FIG. 2B, and FIG. 2C are cross-section views, partial and simplified, of structures obtained at the end of successive steps of an example of a method of manufacturing a power diode according to an embodiment.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as "front", "back", "top", "bottom", "left", "right", etc., or relative position qualifiers, such as "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

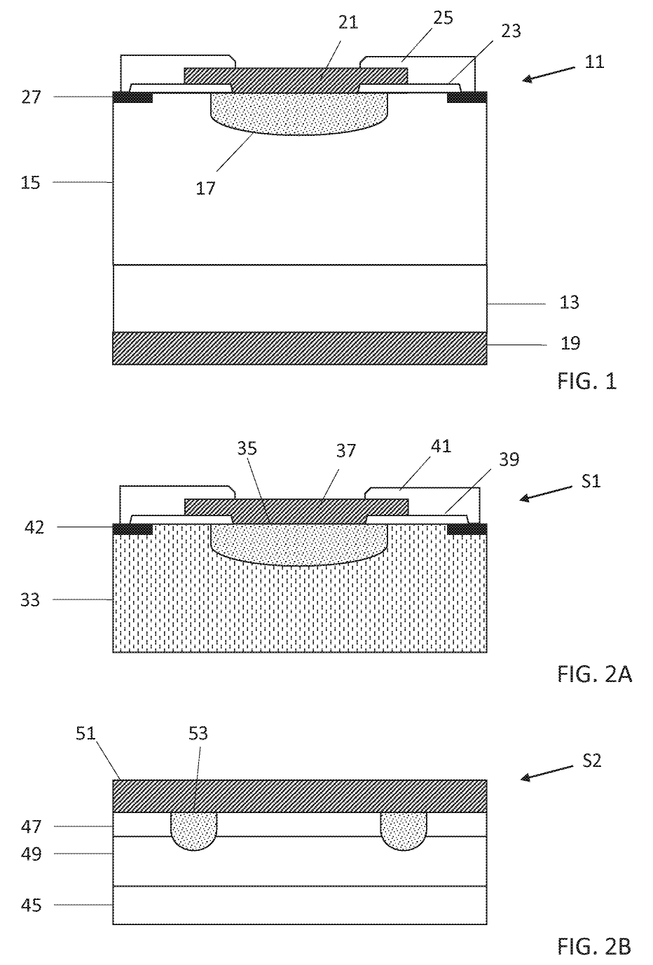

FIG. 1 is a cross-section view, partial and simplified, of an example of a power diode 11.

Power diode 11 comprises a semiconductor substrate 13, topped with a semiconductor layer 15 and with a semiconductor region 17, region 17 being formed in layer 15 and the upper surface of region 17 being flush with the upper surface of layer 15. Layer 15 is for example in contact, by its lower surface, with the upper surface of substrate 13.

Substrate 13 is for example a silicon substrate, for example made of single-crystal silicon.

Substrate 13 is doped with a first conductivity type, for example type N. As an example, substrate 13 is doped with phosphorus atoms. As an example, substrate 13 is doped with a dopant concentration in the order of 10¹⁹ atoms/cm³.

Layer 15 is for example of same nature as substrate 13. Layer 15 is for example made of silicon, for example of single-crystal silicon.

Layer 15 is doped with the same conductivity type as substrate 13, for example type N. As an example, layer 15 is doped with phosphorus atoms. As an example, layer 15 is more lightly doped than substrate 13. Layer 15 is for example doped with a dopant concentration in the order of 10¹⁴ atoms/cm³.

Region 17 is doped with a second conductivity type, opposite to the first conductivity type, for example of type P. As an example, region 17 is doped with boron atoms. As an example, region 17 is more heavily doped than layer 15. As an example, region 17 has a dopant concentration similar to that of substrate 13. Region 17 is for example doped with a dopant concentration in the order of 10¹⁹ atoms/cm³.

As an example, region 17 extends vertically in layer 15 without reaching the upper surface of substrate 13. As an example, region 17 extends in layer 15 down to a depth in the range from 1 µm to 5 µm.

Layer 15 for example has a thickness in the range from 50 µm to 200 µm. Substrate 13 for example has a thickness in the range from 1 µm to 200 µm, for example from 1 µm and 20 µm.

Region 17 corresponds to the anode region of power diode 11, layer 15 corresponds to the lightly-doped region and substrate 13 corresponds to the cathode region of power diode 11.

As an example, diode 11 comprises a metal layer 19 in contact, by its upper surface, with the lower surface of substrate 13. Layer 19 corresponds to a cathode electrode of diode 11. Metal layer 19 for example extends over the entire lower surface of substrate 13.

Diode 11 for example comprises a passivation layer 23 formed on the side of anode region 17. Passivation layer 23 is for example formed on layer 15 and region 17. Layer 23 is for example formed in contact with layer 15 and region 17. As an example, passivation layer 23 entirely covers layer 15 and covers region 17 on a peripheral portion thereof to leave a central portion of region 17 exposed.

Diode 11 further comprises another metal layer 21 in contact, by its lower surface, with the upper surface of region 17. As an example, layer 21 covers the central portion of region 17 left exposed by passivation layer 23. Layer 21 further extends at the surface of the structure so as to cover, and be for example in contact with, a portion of passivation layer 23 formed on top of and around region 17. Layer 21 corresponds to an anode electrode of diode 11.

Layers 21 and 19 are for example made of the same material. As an example, layers 21 and 19 are made of aluminum or of copper.

In the shown example, diode 11 further comprises another passivation layer 25, formed on passivation layer 23. Passivation layer 25 for example covers the upper surface of passivation layer 23 and of metal layer 21. Passivation layer 25 is thus in contact with the upper surface of layer 21 and with the upper surface of passivation layer 23.

As an example, each of passivation layers 23 and 25 is made of an oxide, for example of silicon dioxide, of a nitride, for example of silicon nitride or of polymer, for example of polyimide. Passivation layers 23 and 25 enable among others to limit the electric field present at the surface of power diode 11, that is, at the surface of layer 15 and of region 17.

As an example, diode 11 comprises, in a peripheral portion of region 15, on the upper surface side of region 15, an N-type doped ring-shaped semiconductor layer 27, for example having a doping level higher than that of substrate 13. As an example, region 27 has a dopant concentration in the range from 10¹⁹ atoms/cm³ to 10²⁰ atoms/cm³. Region 27 for example extends in layer 15 while being flush with the upper surface of layer 15. As an example, region 27 extends in layer 15 less deeply than region 17. As an example, in top view, region 27 entirely surrounds region 17, and is separated from region 17 by a portion of layer 15. Region 27 also called stop-channel limits the spread of the substrate 15 space charge so that it does not reach the chip-cutting zone located beyond regions 27.

A diode 11 such as illustrated in FIG. 1 is for example formed by the growth, by epitaxy, of layer 15 from the upper surface of semiconductor substrate 13. As a result, the forming of regions 17 and 27 in layer 15, for example by implantation of dopants from the front side of the structure, that is, the upper surface in the orientation of FIG. 1. After the forming of regions 17 and 27, layers 23, 21, and 25 are for example deposited. Substrate 13 is subsequently thinned from its back side, that is, the lower surface in the orientation of FIG. 1, after which metallization layer 19 is formed on the back side of substrate 13.

Another mode of manufacturing a diode such as illustrated in FIG. 1 consists of the implantation of regions 17 and 27 in a lightly-doped semiconductor substrate, for example having a dopant concentration similar to the concentration of layer 15, from the front side. This results in a thinning of the substrate from the back side, followed by an implantation, in the semiconductor substrate, from the back side, of N-type dopants so as to form, in the semiconductor substrate, cathode region 13 topped with lightly-doped region 15. Layers 23, 21, and 25 and layer 19 are for example formed after the step of dopant implantation allowing the forming of cathode region 13.

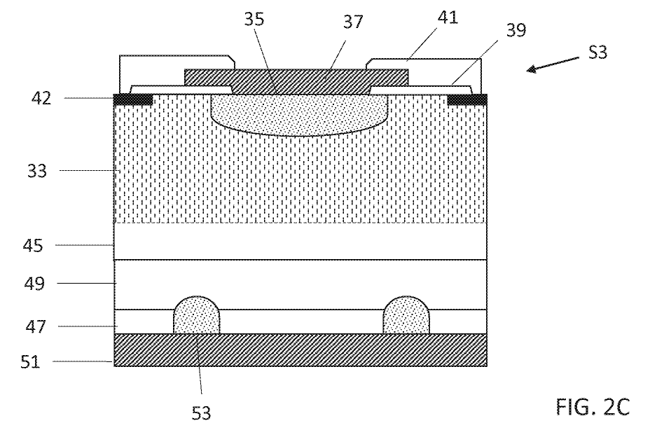

FIG. 2A, FIG. 2B, and FIG. 2C are cross-section views, partial and simplified, of structures obtained at the end of successive steps of an example of a method of manufacturing a power diode according to an embodiment.

FIG. 2A illustrates a first structure S1 comprising a first doped semiconductor substrate 33 of a first conductivity type, for example type N, in which a doped region 35 of the second conductivity type, for example type P, is formed. Region 35 is formed in substrate 33 and is flush with the upper surface of substrate 33. First substrate 33 is for example less heavily doped than region 35.

First substrate 33 is for example doped with phosphorus atoms. As an example, the dopant concentration in substrate 33 is in the range from 10¹³ atoms/cm³ to 10¹⁶ atoms/cm³, and is for example in the order of 10¹⁴ atoms/cm³. Region 35 is for example doped with boron atoms. As an example, the dopant concentration in region 35 is higher than 10¹⁷ atoms/cm³, and is for example in the order of 10¹⁹ atoms/cm³.

Region 35 for example extends vertically from the upper surface of substrate 33 into substrate 33 without reaching the lower surface of substrate 33. As an example, region 35 extends in substrate 33 down to a depth in the range from 1 µm to 3 µm, for example in the order of 2 µm.

Substrate 33 is for example a semiconductor substrate, for example made of silicon, for example of single-crystal silicon. Substrate 33 for example has a thickness in the range from 50 µm to 200 µm, for example in the order of 100 µm.

Substrate 33 further comprises platinum atoms. Substrate 33 for example has a platinum concentration higher than 10¹⁰ atoms/cm³, for example higher than 10¹² atoms/cm³, for example in the order of 10¹⁴ atoms/cm³.

The first structure S1 illustrated in FIG. 2A for example comprises a metal layer 37. Metal layer 37 is for example identical to the metal layer 21 of the diode 11 of FIG. 1. The first structure S1 for example comprises a passivation layer 39. Passivation layer 39 is for example identical to the passivation layer 23 of the diode 11 of FIG. 1. The first structure S1 for example comprises a passivation layer 41. Passivation layer 41 is for example identical to the passivation layer 25 of the diode 11 of FIG. 1. Layers 37, 39, and 41 are for example arranged at the surface of substrate 33 and of region 35 identically to what has been described in relation with FIG. 1 for layers 21, 23, and 25 at the surface of layer 15 and of region 17.

Further, the first structure S1 illustrated in FIG. 2A comprises a ring-shaped region 42 identical to the region 27 illustrated in FIG. 1. Region 42 is for example arranged in substrate 33 identically to what has been described in relation with FIG. 1 for region 27 in layer 15.

The first structure S1 is formed from substrate 33.

Substrate 33 correspond, for example, at the beginning of the method, to a semiconductor wafer or a portion of semiconductor wafer having a thickness in the range from 500 µm to 900 µm, for example in the order of 725 µm.

Region 35 is for example formed by dopant implantation, for example from the front side of substrate 33, corresponding to the upper surface of substrate 33 in the orientation of FIG. 2A. As an example, the dopant implantation step is carried out through a masking layer so as to form region 35 locally in substrate 33.

At the end of the forming of region 35, another implantation step, consisting of forming regions 42, is carried out. As a variant, the order of forming of regions 35 and 42 may be reversed so that regions 42 are formed before the forming of regions 35.

At the end of the forming of regions 35 and 42, a platinum layer is for example deposited on the front side of the structure. At the end of the deposition of the platinum layer, the structure is submitted, for example, to an anneal allowing the diffusion of platinum atoms, from the platinum layer, into substrate 33. As an example, during this anneal, the platinum atoms bond with the silicon atoms present in substrate 33. The anneal for example has a temperature higher than 500°C, for example higher than 800°C, for example in the order of 850°C. The anneal for example has a duration in the range from 30 mins to 24h, for example in the range from 1h to 10h.

At the end of the platinum diffusion in substrate 33, passivation layers 39 and 41 and metallization layer 37 are for example formed on the front side of the structure. As an example, passivation layers 39 and 41 are deposited by a method of atomic layer deposition or ALD. As an example, metallization layer 37 is deposited by a method of physical vapor deposition or PVD. As a variant, metallization layer 37 is deposited by method of electrochemical deposition or ECD.

As an example, at the end of the forming of the metal and passivation layers, the structure is thinned from its back side. The thinning step is for example carried out by mechanical polishing. The thinning step further comprises for example a step of chemical mechanical polishing or CMP in order to obtain a low roughness on the surface of the structure, for example an arithmetic average roughness of the order of 1 nm. The structure is, for example during this step, bonded to a support plate, from its front side, the support plate having the function of solidifying and rigidifying the structure, facilitating its handling. At the end of this step, substrate 33 has a thickness in the range from 50 µm to 200 µm, for example in the order of 100 µm.

FIG. 2B illustrates a second structure S2 comprising a second doped semiconductor substrate 45 of the first conductivity type, type N in this example, on which is formed a doped semiconductor layer 47 also of the first conductivity type, substrate 45 being less heavily doped than semiconductor layer 47. For example, the second semiconductor substrate 45 has a higher concentration of doping elements than the first semiconductor substrate 33.

As an example, structure S2 comprises an intermediate semiconductor layer 49, called field stop layer, between layer 47 and substrate 45. Layer 49 is for example in contact, by its lower surface, with the upper surface of substrate 45. As an example, layer 49 is in contact, by its upper surface, with the lower surface of layer 47.

Layer 49 is, however optional, and it can be provided that the layer 47 is directly in contact with the upper face of the substrate 45, the field-stop function being ensured by the thickness of the substrate 45.

As an example, layer 47 extends over the entire upper surface of substrate 45. Layer 49 extends, for example, over the entire upper surface of substrate 45. Layer 49 is for example doped with the first conductivity type, for example type N. As an example, layer 49 is more heavily doped than substrate 45. Layer 49 is for example less heavily doped than layer 47.

As an example, substrate 45 has a dopant concentration in the range from 10¹³ atoms/cm³ to 10¹⁶ atoms/cm³, for example in the order of 10¹⁴ atoms/cm³. The doping level of substrate 45 is for example substantially equal to the doping level of substrate 33. Substrate 45 is for example deprived of platinum atoms.

As an example, layer 47 has a dopant concentration higher than 10¹⁷ atoms/cm³, for example in the order of 10¹⁹ atoms/cm³.

As an example, layer 49 has a dopant concentration in the range from 10¹⁴ atoms/cm³ to 10¹⁹atoms/cm³, for example in the order of 10¹⁶ atoms/cm³.

As an example, layer 47 has a thickness in the range from 1 µm to 20 µm, for example in the order of 5 µm.

As an example, layer 49 has a thickness in the range from 2 µm to 50 µm, for example in the order of 5 µm.

As an example, substrate 45, layer 47, and layer 49 altogether have a thickness in the range from 10 µm to 60 µm, for example in the order of 30 µm.

As an example, the second structure S2 comprises doped regions 53 of the second conductivity type, for example type P, formed in layers 47 and 49. As an example, regions 53 have a dopant concentration similar to the dopant concentration of the region 35 of the first structure S1. As an example, regions 53 are flush with the upper surface of layer 47. As an example, regions 53 extend in layers 47 and 49 without protruding from the lower surface of layer 49.

The second structure S2 illustrated in FIG. 2B further comprises for example a metal layer 51, covering layer 47 and regions 53. As an example, layer 47 is identical to the metal layer 19 illustrated in FIG. 1.

The second structure S2 is formed from the substrate 45 on which layers 47 and 49 are formed, for example by epitaxy. Layers 47 and 49 are for example doped in-situ during the epitaxial growth.

As an example, the epitaxy is not interrupted between the phase of growth of layer 49 and the phase of growth of layer 47. Only the dose of implanted dopant elements is increased.

Alternatively, layers 47 and 49 are formed by implanting or diffusing doping elements into substrate 45.

The steps of epitaxy and implantation are for example formed from the back side of the structure, corresponding to the upper surface of the structure in the orientation of FIG. 2B.

At the end of the forming of layers 47 and 49, regions 53 are for example formed by implantation through a mask. Further, at the end of these steps, metal layer 51 is for example formed on the back side of the structure, that is, the upper surface of the structure in the orientation of FIG. 2B.

The structure is for example, at the end of this step, bonded to a support plate by its back side. The support plate for example enables to solidify and rigidify the structure, facilitating its handling. As an example, at the end of these steps, the structure is thinned from its front side, that is, the lower surface of the structure in the orientation of FIG. 2B. The thinning step is for example carried out by mechanical polishing. For example, the thinning step further comprises a step of CMP in order to obtain a low roughness on the surface of the structure, for example an arithmetic average roughness of less than 1 nm.

FIG. 2C illustrates a third structure S3 resulting from the bonding of the first structure S1, illustrated in FIG. 2A, to the second structure, illustrated in FIG. 2B. More particularly, during this bonding step, the first structure S1 illustrated in FIG. 2A is bonded, by its lower surface, to the lower surface of the second structure S2 illustrated in FIG. 2B.

More particularly, during this step, the surface of substrate 33 opposite to region 35 (that is, the lower surface of substrate 33 in the orientation of FIG. 2A) is bonded to the surface of substrate 45 opposite to layer 47 (that is, the lower surface of substrate 45 in the orientation of FIG. 2B).

The bonding step is for example a direct bonding or molecular bonding step, for example a step of bonding by hydrophobic bonds. As an example, it here is a bonding of silicon-to-silicon type.

According to a first implementation mode, the bonding is performed by a method of atomic diffusion bonding or ADB.

This method consists of the deposition of a film on the surfaces of the two structures to be bonded. This enables to create, at the surface of the sides to be placed into contact, dangling bonds. As an example, to form the film, a beam of ions or atoms, for example of neutral gas, bombards a target made of a material having its atoms detaching and uniformly depositing in a film onto one and the other of the surfaces to be bonded. As an example, the target is metallic, for example made of titanium. As a variant, the target is made of a semiconductor material, for example, of silicon, of aluminum nitride. Still as a variant, the target is made of aluminum oxide. This step is carried out under vacuum, that is, at a pressure lower than the atmospheric pressure, for example under ultrahigh vacuum, for example under a pressure lower than 10⁻⁷ mbar, for example lower than 10⁻⁸ mbar. The dangling bonds of the surfaces of the two structures to be bonded create, when they are placed into contact, covalent bonds ensuring the bonding of the two structures.

According to a second implementation mode, the bonding is carried out by a method of surface activated bonding or SAB.

This method consists of an ion etching or abrasion method aiming at sending, onto the surfaces of the two structures to be bonded, a beam of ions or of atoms, for example neutral. It is here spoken of a surface activation. The beam enables to remove, for example, possible native oxides formed at the surface and to form dangling bonds at the surface of the surfaces to be placed into contact. It is here spoken of activated surfaces. This step is carried out under vacuum, that is, at a pressure lower than the atmospheric pressure, for example under ultrahigh vacuum, for example under a pressure lower than 10⁻⁷ mbar, for example lower than 10⁻⁸ mbar. Similarly to what has been described in the previous implementation mode, the dangling bonds of the surfaces of the two structures to be bonded create, when they are placed into contact, covalent bonds ensuring the bonding of the two structures.

According to a third implementation mode, the bonding is carried out by a method of bonding by reconstructed surfaces.

This bonding method consists of the cleaning of the surfaces to be bonded with an oxidizing solvent and then of a step of chemical deposition of a silicon film, for example in vapor phase at a reduced pressure. The step of deposition of the film more precisely comprises an anneal step in order to reduce the chemical oxide resulting from the cleaning, and then an epitaxy step, so as to form a silicon film, and eventually another anneal to complete the surface reconstruction.

According to a fourth implementation mode, the bonding is performed by a method of bonding with dilute hydrofluoric acid (HF).

This method consists of placing into contact the structures to be bonded in the presence of HF. Here, the two structures are for example coupled together by covalent bonds formed between hydrogen atoms and fluorine atoms present on one and/or the other of the structures natively or originating from the bonding of an HF molecule. A bond between a hydrogen atom present at the surface of one of the structures with a fluorine of an HF molecule having its hydrogen bonded to a silicon atom present at the surface of the other of the structures may thus be provided. This type of method generates a bonding between rough surfaces of two structures, via the asperities of the two surfaces.

After the bonding step, to solidify the bonding of the first structure to the second structure, an anneal is for example carried out at a temperature lower than 400°C.

At the end of these steps, there results a third structure S3 in which the platinum concentration in the first substrate 33 is higher than the platinum concentration in the second substrate 45.

An advantage of the forming of the diode by the bonding of two structures formed separately is that this enables to form anode and cathode electrodes independently from each other. Thus, the steps of forming of the metal and passivation layers are facilitated. Indeed, the step of forming of the cathode electrode is not limited in temperature due to the fact that anode electrode 37 and passivation layers 39 and 41 have not been previously formed on the same structure.

Another advantage of the forming of the diode by the bonding of two structures formed separately is that this allows a presence of platinum in the lightly-doped region of the diode only in the vicinity of the anode region. The presence of platinum in the vicinity of the anode region but its absence in the vicinity of the cathode region enables to improve the electric performance and in particular the decrease in the reverse recovery time or Trr. The speed of switching between the conductive and non-conductive states is thus increased.

Another advantage of the forming of the diode by the bonding of two structures formed separately is that this enables to control the depth of field stop layer 49. Field stop layer 49 can thus be deeper, as compared with a layer 49 formed by laser dopant implantation, thus improving the field stop performance and decreasing leakage currents at the back side of the structure.

Another advantage of the forming of the diode by the bonding of two structures formed separately and of the dopant implantation during the epitaxy step, so as to form layers 47 and 49, is that this enables to form a structure comprising a difference in the N-type dopant concentration between layer 47 and layer 49, which enables to improve the field stop performance while decreasing the leakage currents at the back side of the structure.

Another advantage of the forming of the diode by the bonding of two structures formed separately is that this enables to form field stop layer 49, by epitaxy, thus limiting the introduction of defects at the interface between substrate 45 and layer 49, as compared with a step of forming of layer 49 by implantation of dopants with a laser into a lightly-doped substrate.

Various embodiments and variants have been described. Those skilled in the art will understand that certain features of these various embodiments and variants may be combined, and other variants will occur to those skilled in the art. The described embodiments are not limited to the examples of dimensions and of materials mentioned hereabove.

Further, although the embodiment of FIGS. 2A to 2C provides a field stop layer 49, it may be provided for this layer to be omitted and for layer 47 to be formed on top of and in contact with substrate 45. In such substructure, layer 47 stops the field in the vicinity if the back face of structure S3.

Further, although the embodiment of FIGS. 2A to 2C provides regions 42 and 53, it may be provided for all or part of these regions to be omitted.

Again, although not shown, an annular region can be formed in substrate 33, between region 35 and region 42, to stop the lateral field. Such a region may be doped with the second type of conductivity. By way of example, this region may have a lower doping element concentration than the doping element concentration of region 35. This region may for example have a doping element concentration of between 10¹⁵ atoms/cm³ and 10¹⁶ atoms/cm³.

Finally, the practical implementation of the described embodiments and variants is within the abilities of those skilled in the art based on the functional indications given hereabove.

Many applications can benefit from the advantages of the power diode, as it can be integrated into various types of component.

By way of example, the diode can be integrated into a component intended for the automotive industry and, more specifically, in electric vehicles. In particular, power diodes can be used in Battery Management Systems (BMS) to manage the charging and discharging cycles of the battery, ensuring efficient power flow and protection against overvoltage. Power diodes can also be used in inverters, where they convert DC power from the battery to AC power for the electric motor. Power diodes can also be used in regenerative braking systems, where they efficiently recover energy during braking, which is then fed back into the battery.

By way of example, the diode can be integrated into a component designed for the Internet of Things (IoT). In particular, power diodes can be used in smart meters, where they provide efficient energy conversion and protection against voltage spikes. Diodes can also be used in power regulation circuits to ensure stable operation of IoT gateways. Power diodes can also be used in sensor nodes, where they help to manage power, ensuring they operates efficiently and reliably.

By way of example, the diode can be integrated into a component for use in industrial automation. In particular, power diodes are used in motor drive control circuits to manage power flow and protect against voltage spikes. Power diodes can also be used in industrial power supplies, where they convert AC to DC and regulate voltage levels. Power diodes can also be used in the power management circuits of robotic systems to ensure efficient operation and protection.

By way of example, the diode can be integrated into a component for use in personal electronics equipment. In particular, power diodes can be used in charging circuits in smartphones to manage power flow and protect against overvoltage. Power diodes can also be used in power regulation circuits in laptops to ensure efficient laptop operation and protect against power surges. Power diodes can also be used in wearable devices, where they help manage power to ensure they operate efficiently and have longer battery life.

The power diode described in the patent application has broad other commercial applications due to its high-frequency operation, high reverse voltage tolerance and fast switching capabilities. These features make it suitable for use in electric vehicles, IoT devices, industrial automation systems and personal electronics.

What is claimed is:

1. A method of manufacturing a power diode comprising the following steps:
a. forming a first structure comprising a first semiconductor substrate doped with a first conductivity type, and, in the first semiconductor substrate, on a side of a first surface of the first semiconductor substrate, a first doped region of a second conductivity type, opposite to the first conductivity type;
b. forming a second structure comprising a second semiconductor substrate, and, on the second semiconductor substrate, on the side of a first surface of the second semiconductor substrate, a first layer, the second semiconductor substrate and the first layer being doped with the first conductivity type, the first layer being more heavily doped than the second semiconductor substrate;
c. diffusing platinum atoms in the first semiconductor substrate; and
d. assembling the first structure and the second structure by placing into contact a second surface of the first semiconductor substrate of the first structure, opposite to the first surface, and a second surface of the second semiconductor substrate of the second structure, opposite to the first surface,
wherein at step d., the second semiconductor substrate is deprived of platinum atmos.

2. The method of manufacturing a power diode of claim 1, wherein, during step b., the first layer is formed by epitaxy on the first surface of the second semiconductor substrate.

3. The method of manufacturing a power diode of claim 1, wherein the second structure formed during step b. further comprises a field stop layer between the second semiconductor substrate and the first layer, the field stop layer being doped with the first conductivity type.

4. The method of manufacturing a power diode of claim 3, wherein the field stop layer is formed by epitaxy on the first surface of the second semiconductor substrate.

5. The method of manufacturing a power diode of claim 1, wherein during step a., the first doped region is formed by implantation of dopants from the first surface of the first semiconductor substrate.

6. The method of manufacturing a power diode of claim 1, wherein step c. comprises forming a platinum metal layer on the first surface of the first semiconductor substrate of the first structure and annealing a structure thus obtained to obtain a platinum diffusion in the first semiconductor substrate.

7. The method of manufacturing a power diode of claim 1, wherein step d. is carried out by an atomic diffusion bonding method.

8. The method of manufacturing a power diode of claim 1, wherein step d. is carried out by a surface activation bonding method.

9. The method of manufacturing a power diode of claim 1, wherein step d. is carried out by a dilute hydrofluoric acid bonding method.

10. The method of manufacturing a power diode of claim 1, wherein step d. is carried out by a reconstructed surface bonding method.

11. The method of manufacturing a power diode of claim 1, wherein the first semiconductor substrate comprises a platinum concentration higher than a platinum concentration in the second semiconductor substrate.
